(19) United States
(12) Patent Application Publication
(10) Pub. No.: US 2026/0110074 A1
(43) Pub. Date: Apr. 23, 2026

(54) ALUMINUM NITRIDE THIN FILM DEPOSITION USING SPUTTERING

(71) Applicants: The Regents of the University of California, Oakland, CA (US); Georgia Tech Research Corporation, Atlanta, GA (US)

(72) Inventors: Andrew Kummel, LaJolla, CA (US); Ping-Che Lee, San Diego, CA (US); Diego Contreras Mora, La Jolla, CA (US); Dohyun Go, La Jolla, CA (US); Satish Kumar, Atlanta, GA (US); Mingeun Choi, Atlanta, GA (US)

(21) Appl. No.: 19/366,019

(22) Filed: Oct. 22, 2025

Related U.S. Application Data
(60) Provisional application No. 63/710,945, filed on Oct. 23, 2024.

(51) Int. Cl. C23C 14/06; C23C 14/34; C23C 14/35; C23C 14/54

(52) U.S. Cl. CPC C23C 14/0617; C23C 14/3414; C23C 14/3485; C23C 14/35; C23C 14/54

(57) ABSTRACT

Methods and systems are disclosed for depositing aluminum nitride thin films by reactive sputtering using a sequence of negative-polarity voltage pulses applied to an aluminum target, followed by a positive-polarity voltage pulse. HiPIMS-type waveforms may be used to implement the negative-polarity and/or positive-polarity pulses. A substrate is provided in a sputtering chamber, a process gas comprising an inert gas and a nitrogen-containing gas is introduced, and the chamber is maintained at a reduced pressure. A sequence of negative-polarity voltage pulses is applied to an aluminum target, followed by application of a positive-polarity voltage pulse to the target. The disclosed methods and systems can produce aluminum nitride thin films exhibiting improved crystallinity, thermal conductivity, and surface quality at reduced deposition temperatures (e.g., below 200° C.) and with deposition rates of at least about 50 nm/min suitable for industrial applications.

### RELATED APPLICATIONS

This application claims the benefit of priority under 35 U.S.C. § 119(e) to U.S. Provisional Patent Application No. 63/710,945, filed Oct. 23, 2024, entitled “Low-Pressure HiPIMS Method for Rapid Deposition of High-Thermal Conductivity Aluminum Nitride Film,” which is incorporated herein by reference. This application is related to the publication entitled “Achieving a High Thermally Conductive One Micron AlN Deposition by High Power Impulse Magnetron Sputtering plus Kick,” published in ACS Applied Materials & Interfaces in May 2024, which is incorporated herein by reference in its entirety for all purposes. Any and all applications for which a foreign or domestic priority claim is identified in the Application Data Sheet as filed with the present application are incorporated by reference under 37 CFR 1.57 and made a part of this specification.

### STATEMENT OF GOVERNMENT SUPPORT

This invention was made with government support under Grant No. HR0011-23-3-0002 awarded by the Department of Defense/Defense Advanced Research Projects Agency (DARPA). The government has certain rights in the invention.

### FIELD

The present disclosure relates to thin-film deposition for semiconductor devices and packaging, and more particularly to reactive physical vapor deposition techniques for forming aluminum nitride films.

### BACKGROUND

Aluminum nitride (AlN) thin films are widely used in semiconductor devices and packaging due to their high thermal conductivity, electrical insulation, and compatibility with integrated circuit processes. As device power densities increase, there is a continued demand for films that combine efficient heat dissipation with low surface RMS roughness (<0.5 nm).

Conventional deposition approaches, such as chemical vapor deposition and various sputtering techniques, face challenges in simultaneously achieving high throughput, smooth morphology, and desired crystal orientation. Reactive sputtering is often limited by process hysteresis, target poisoning, and narrow process windows, which complicate the stable production of uniform AlN films.

Unipolar-High-power impulse magnetron sputtering (HiPIMS) has been explored to improve ionization and film density, but it reduces deposition rate and adds process complexity. Control of plasma conditions, working pressure, and pulse sequencing remain important to balance deposition rate, film quality, and stability. Accordingly, there is an ongoing need for deposition techniques that reproducibly deliver high-quality AlN thin films under conditions suitable for semiconductor manufacturing.

### SUMMARY

Methods and systems are disclosed for depositing aluminum nitride thin films by reactive sputtering using a sequence of negative-polarity voltage pulses applied to an aluminum target, followed by a positive-polarity voltage pulse. HiPIMS-type waveforms may be used to implement the negative-polarity and/or positive-polarity pulses. A substrate is provided in a sputtering chamber, a process gas comprising an inert gas and a nitrogen-containing gas is introduced, and the chamber is maintained at a reduced pressure. A sequence of negative-polarity voltage pulses is applied to an aluminum target, followed by application of a positive-polarity voltage pulse to the target. The disclosed methods and systems can produce aluminum nitride thin films exhibiting improved crystallinity, thermal conductivity, and surface quality at reduced deposition temperatures (e.g., below 180° C.) and with deposition rates of at least about 60 nm/min suitable for industrial applications.

### BRIEF DESCRIPTION OF THE DRAWINGS

Throughout the drawings, reference numbers can be re-used to indicate correspondence between referenced elements. The drawings are provided to illustrate embodiments of the present disclosure and do not limit the scope thereof.

FIG. 1A is a schematic diagram of a multilayer structure prepared for frequency-domain thermoreflectance (FDTR) measurement of thermal conductivity and thermal boundary conductance.

FIG. 1B illustrates graphs of target current plotted against time, showing the strong dependence of reactive HiPIMS plasma stability on the applied pulsing frequency at 0.5 Pa.

FIG. 1C illustrates graphs of target current versus time at a working pressure of 0.7 Pa.

FIG. 1D illustrates plots of discharge current and applied voltage versus time under high-frequency operation.

FIG. 1E illustrates plots of discharge current and applied voltage versus time under low-frequency operation.

FIG. 2A illustrates the relationship between nitrogen flow rate, target voltage, and chamber pressure obtained from a DC hysteresis study using HiPIMS plus kick (bipolar HiPIMS).

FIG. 2B illustrates the resulting surface composition identified by surface XPS, showing 41% nitrogen, 6% oxygen, and 45% aluminum.

FIGS. 3A-3E collectively illustrate the influence of the positive “kick” voltage, applied during HiPIMS plus kick (bipolar HiPIMS) deposition, on the cross-section morphology and grain structure of AlN films.

FIGS. 4A-4E collectively illustrate the influence of positive kick pulse width in HiPIMS plus kick (bipolar HiPIMS) deposition on the structure and crystallinity of AlN films.

FIGS. 5A-5C illustrate cross-sectional SEM images of AlN films deposited with main negative pulse widths of 15 μs, 20 μs, and 25 μs, respectively, during applied HiPIMS plus kick (bipolar HiPIMS).

FIG. 5D illustrates X-ray diffraction (XRD) spectra of the same films, showing the XRD (002) diffraction peaks.

FIG. 5E illustrates omega rocking curve scans of the same films.

FIGS. 6A and 6B illustrate the full width at half maximum (FWHM) of the omega rocking curve as a function of film thickness for AlN films deposited on Si(100) substrates at working pressures of 1.0 Pa and 0.5 Pa, respectively.

FIG. 6C illustrates the evolution of the rocking curve (RC) FWHM as a function of thickness for AlN films deposited on a thermal amorphous SiO₂ layer supported by a Si substrate at a working pressure of 0.5 Pa.

FIG. 7A illustrates a high-resolution transmission electron microscopy (HRTEM) image of the grain structure of a 1.5 μm-thick bulk AlN film deposited via low-pressure HiPIMS plus kick (bipolar HiPIMS).

FIG. 7B illustrates the interface between crystalline AlN and amorphous native SiO₂ via low-pressure HiPIMS plus kick (bipolar HiPIMS).

FIG. 7C is an atomic force microscopy (AFM) image of an aluminum nitride thin film deposited using bipolar high power impulse magnetron sputtering combined with a −40 V positive voltage pulse.

FIG. 8A illustrates a comparison of the 0.4 μm and 1 μm room-temperature cross-plane thermal conductivity of AlN films deposited by HiPIMS plus kick (bipolar HiPIMS) with values reported in the literature.

FIG. 8B illustrates normalized growth rates of AlN films reported in the literature compared with the present HiPIMS plus kick (bipolar HiPIMS) study.

FIG. 8C schematically depicts the influence of nitrogen fraction on target poisoning in HiPIMS and DC sputtering.

FIG. 9 is a flow diagram illustrative of an embodiment of a routine for depositing an aluminum nitride thin film using sputtering.

### DETAILED DESCRIPTION

### Introduction

Aluminum nitride (AlN) thin films have been widely researched in the semiconductor industry due to their insulating properties, mechanical strength, and wide optical band gap. The increasing demand for high-speed computing has sparked renewed interest in AlN thin films, particularly for their role in efficient heat dissipation in chips as heat spreader layers. Alternative materials such as boron nitride (BN) and diamond have not achieved industrial adoption due at least in part to limitations in production processes. Diamond growth using chemical vapor deposition (CVD) is often hindered by issues of surface roughness, while hexagonal boron nitride (h-BN) often requires extremely high temperatures for CVD growth or, when deposited via sputtering, tends to exhibit mixed phase.

Various sputtering techniques, including balanced magnetron sputtering, are commonly used to deposit polycrystalline AlN thin films. These methods are considered ideal due to their well-established CMOS (Complementary Metal-Oxide-Semiconductor)-compatible deposition processes. Plasma-related Physical Vapor Deposition depositions are known in the semiconductor industry for enhancing surface diffusion through energetic ions or radicals that facilitate chemical reactions. However, these deposition techniques face challenges, particularly with slow deposition rates in either balanced or unbalanced magnetron configuration. High Power Impulse Magnetron Sputtering (HiPIMS) with an additional positive kick bias—a form of bipolar sputtering—has attracted increasing research interest due to its capability to enhance the ionization fraction of sputtered metal species, ranging from ˜9% to 70% depending on pulse duration and target material. This elevated ionization facilitates improved adatom mobility, resulting in denser microstructures and smoother film morphologies. The kick refers to a short, high-voltage pulse applied immediately after the main HiPIMS pulse. This secondary pulse accelerates ions through the plasma sheath, improving film density. Despite this, HiPIMS typically has a deposition rate of around 50% lower than DC (Direct Current) sputtering due to the self-sputtering effect. Additionally, there are limited studies on AlN films deposited using either monopolar HiPIMS or HiPIMS plus kick (sometimes referred to or known as bipolar HiPIMS).

A deposition rate of 60 nm/min (0.18 nm/W·min) for AlN films was achieved using HiPIMS plus kick (bipolar HiPIMS) with less than 0.5 Pa working pressure, while maintaining single-texture growth on a lattice-mismatched Si(100) substrate and achieving cross plane thermal conductivity levels in the range of 120-160 W/m·K. Because the thermal properties of AlN depend strongly on crystallinity, both the kick (positive 2^{nd} pulse after the 1^{st} large negative pulse to the target) and the operating pressure can be important for achieving high-quality AlN heat spreader films.

Reactive HiPIMS sputtering at such low pressure offers distinct advantages for achieving high-quality films but also poses challenges due to the stringent process control required and the inherent instability of transient HiPIMS plasmas. These or other limitations can be addressed by operating at higher pulsing frequencies, which can sustain the plasma and provide stable discharge conditions at low pressure. Such techniques may enable consistent film growth and reproducible results.

Experimental optimization of the 0.5 Pa gas composition for HiPIMS plus kick (bipolar HiPIMS) AlN deposition focused on the metal-to-nitride transition as an important reference point, enabling a high deposition rate while reducing surface oxygen contamination. Using an optimization technique similar to that employed for high pressure HiPIMS plus kick (bipolar HiPIMS), the kick pulse parameters for low pressure HiPIMS plus kick (bipolar HiPIMS) were refined to optimize single-texture growth, as evidenced by X-ray diffraction (XRD) and the narrow FWHM of the rocking curve (RC), indicative of high crystal quality.

### Experiment

Substrate Preparation. In one embodiment, Si(100) substrates having a sheet resistance of about 10 ohm/square were employed. The substrates were subjected to a degreasing sequence including acetone, methanol, isopropanol, and deionized water. Hydrofluoric acid cleaning was not performed, such that the substrates retained a native oxide layer of less than about 2 nm as confirmed by transmission electron microscopy (TEM). For insulating substrate studies, Si(200) substrates having a thermal oxide layer of approximately 1 μm were subjected to the same cleaning process. Nearly any substrate can be employed both insulating and conductive.

HiPIMS Plus Positive Pulse Deposition. A bipolar pulsing signal was generated under constant-voltage regulation from a HiPIMS impulse power unit supplied by a direct-current power source. The input voltage and output peak target current were monitored with a digital storage oscilloscope. A magnetron sputter cathode having a balanced magnetic configuration was utilized. The sputtering target included aluminum with a diameter of about 2 inches, a thickness of about 0.25 mm, and a nominal purity of 99.999%. The vacuum chamber included a main body of approximately 10 inches in diameter and was evacuated by a turbomolecular pump. The target-to-substrate distance was maintained at about 7 cm. Depositions were conducted at a substrate temperature of about 120° C. The working pressure was measured using a capacitance manometer. The process was operated in constant-voltage mode, and the discharge power exhibited a fluctuation of approximately 10%, ranging from about 330 W to about 370 W.

The process can include four illustrative aspects: frequency, nitrogen concentration, positive pulse voltage, and pulse width. It should be understood that fewer, additional, or alternative aspects may be employed, and the order of steps may be varied, depending on the desired implementation.

Frequency Adjustment. A process including 1 sccm nitrogen flow at a working pressure of 0.5 Pa, with a 20 μs, 540 V main negative pulse and a 40 V, 100 μs positive pulse, was carried out to examine the role of frequency in HiPIMS plasma.

Part 2: Nitrogen Adjustment. An MDX 1K DC power supply operated at approximately 150 W was utilized to conduct a hysteresis study to determine the transition point of the target from Al metal to AlN ceramic. The results of the hysteresis study were applied in a 2000 Hz, 540 V, 20 μs HiPIMS plasma to study behavior at 0.5 Pa argon background pressure.

Part 3: Positive Kick Voltage Variation. In the study addressing the positive pulse, the process parameters established from the foregoing conditions (1 sccm nitrogen flow at 0.5 Pa working pressure with a 20 μs, 540 V main negative pulse, a fixed 100 μs positive pulse width, and a 2000 Hz repetition frequency) were employed, and the positive pulse amplitude was varied from 30 V to 50 V to examine the impact on incident ion energy.

Part 4: Positive Kick Length Variation. To examine the influence of pulse duration, the process parameters from the foregoing conditions were employed: 1 sccm nitrogen flow at 0.5 Pa working pressure, a fixed 540 V, 20 μs main negative pulse, a fixed 40 V positive pulse amplitude, and a 2000 Hz repetition frequency. The positive pulse length was varied from 50 μs to 150 μs to examine the effect on incident ion energy.

Table 1 sets forth illustrative process conditions for reactive sputter deposition of aluminum nitride using high-power impulse magnetron sputtering with a subsequent positive pulse. In certain embodiments, the process gas includes about 26.8% nitrogen, the HiPIMS pulse width is about 20 μs, the target voltage is about 540 V under constant-voltage operation, the repetition frequency is about 2000 Hz, and the working pressure is about 4 mTorr. As shown, individual studies were conducted by varying a single parameter while maintaining the remaining parameters substantially constant. In one set, the frequency and nitrogen content were established within a plasma-sustaining window at approximately the foregoing baseline. In another set, the amplitude of the post-pulse positive bias (e.g., about 30 V, about 40 V, about 50 V) was varied at a fixed positive-pulse duration of about 100 μs. In a further set, the duration of the positive pulse (e.g., about 50 μs, about 100 μs, about 150 μs) was varied at a fixed amplitude of about 40 V. In another set, the main negative pulse length (e.g., about 15 μs, about 20 μs, about 25 μs) was varied while the positive-pulse settings were held constant. The rightmost column identifies an example combination of the foregoing conditions that was used to produce aluminum nitride films exhibiting the desired texture and morphology; this combination is provided by way of example and without limitation.

TABLE 1

| | Frequency & | Positive Kick | | | Positive Kick | | | Negative | | | Optimized |
|---|---|---|---|---|---|---|---|---|---|---|---|
| | Nitrogen | Voltage | | | length | | | main length | | | Growth |
| | Optimization | Optimization | | | Optimization | | | Optimization | | | Condition |
| N₂ | 26.8 | 26.8 | | | 26.8 | | | 26.8 | | | 26.8 |
| concentration | | | | | | | | | | | |
| (%) | | | | | | | | | | | |
| HiPIMS | 20 | 20 | | | 20 | | | 20 | | | 20 |
| pulse width | | | | | | | | | | | |
| (μs) | | | | | | | | | | | |
| Voltage (V) | 540 | 540 | | | 540 | | | 540 | | | 540 |
| Frequency | 2000 | 2000 | | | 2000 | | | 2000 | | | 2000 |
| (Hz) | | | | | | | | | | | |
| Negative | 20 | 20 | | | 20 | | | 15 | 20 | 25 | 20 |
| main length | | | | | | | | | | | |
| Kick Voltage | 40 | 30 | 40 | 50 | 40 | | | 40 | | | 40 |
| (V) | | | | | | | | | | | |
| Kick Pulse | 100 | 100 | | | 50 | 100 | 150 | 100 | | | 100 |
| (μs) | | | | | | | | | | | |
| Deposition | 4 | 4 | | | 4 | | | 4 | | | 4 |
| Pressure | | | | | | | | | | | |
| (mtorr) | | | | | | | | | | | |

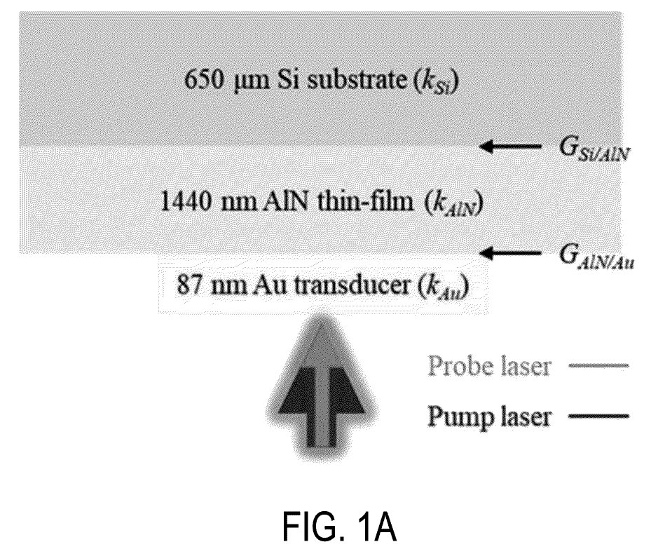

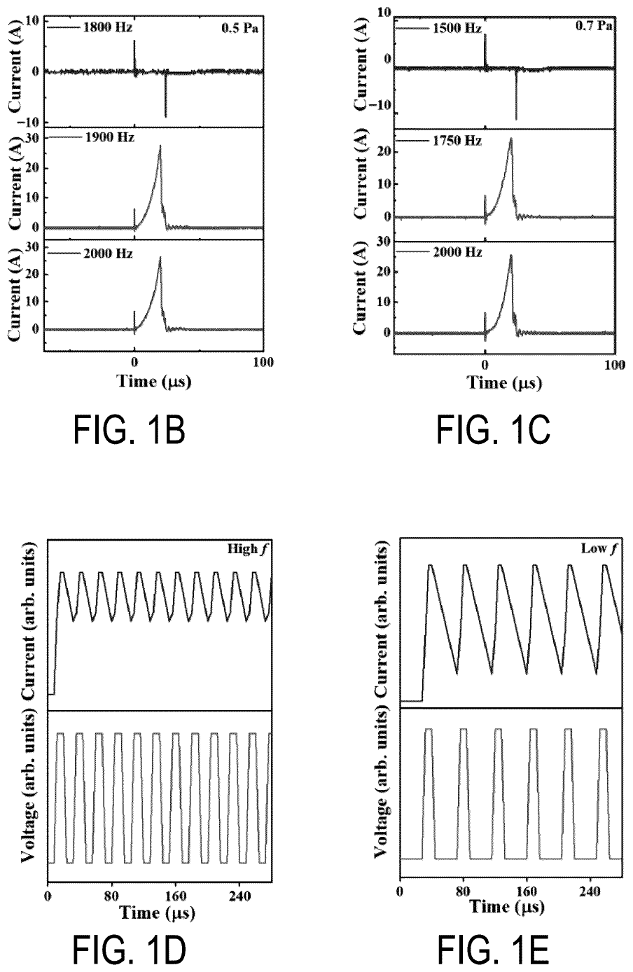

The experiments conducted at 0.7 Pa and 0.5 Pa, as illustrated in FIGS. 1B-1E, were carried out to examine plasma behavior rather than film properties. Plasma ignition was first established in argon at 1.8 Pa by applying a discharge voltage of 700 V at a pulsing frequency of 2000 Hz. After ignition, the discharge voltage was reduced to 540 V, and the pulsing frequency and chamber pressure were adjusted in a controlled manner to reach values of 0.5 Pa and 0.7 Pa.

The experiment at 1.0 Pa was conducted separately from the foregoing study. This process employed a discharge of 540 V in HiPIMS with a 20 μs negative pulse at 600 Hz, a chamber pressure of 1.0 Pa with approximately 17% nitrogen, and a positive bias pulse of +25 V for 50 μs, with the substrate maintained at about 180° C.

### Frequency-Domain Thermal Reflectance Measurements (FDTR)

To determine the cross plane thermal conductivity of the AlN film (kₐₗₙ) and the thermal boundary conductances (TBCs) at the Au/AlN (Gₐᵤ/ₐₗₙ) and AlN/Si (Gₐₗₙ/ₛᵢ) interfaces, frequency-domain thermoreflectance (FDTR) measurements were conducted on the AlN film sample, as shown in FIG. 1A.

FIG. 1A is a schematic diagram of a multilayer structure prepared for frequency-domain thermoreflectance (FDTR) measurement of cross plane thermal conductivity and thermal boundary conductance. The structure can include a silicon substrate, such as a substrate having a thickness of about 650 μm, an aluminum nitride thin film deposited on the substrate, such as a film having a thickness of about 1440 nm, and a gold transducer layer, such as a layer having a thickness of about 87 nm, disposed on the aluminum nitride film. During FDTR measurement, a pump laser can be directed onto the surface of the gold transducer to induce localized heating, and a probe laser can detect the reflected thermal response. Analysis of the resulting frequency-dependent phase lag between the pump and probe beams can enable extraction of cross plane thermal conductivity of the aluminum nitride film and the thermal boundary conductances at the Au/AlN and AlN/Si interfaces.

A modulated 488 nm continuous-wave (CW) pump laser induces localized heating in the Au layer, while a 520 nm CW probe laser detects the reflected thermal waves. The phase lag (φ) between the pump and probe lasers was measured as a function of the modulation frequency (f) of the pump laser. The thermal properties were extracted by fitting the experimental phase data, φ(f), to a theoretical thermal transport model that solves the heat diffusion equations in cylindrical coordinates for a multilayer structure.

Two different 1.5 μm-thick AlN samples—each exhibiting a distinct cross plane thermal conductivity—were investigated using the same FDTR setup. These two samples, which were subsequently found to have thermal conductivities of 125.9 W/m·K and 159.9 W/m·K, respectively, were examined over a modulation frequency range from 10 kHz to 3 NMz to ensure sensitivity to both the film's thermal conductivity and the TBCs at its interfaces. This frequency range corresponds to thermal penetration depths (dₚ) of approximately 45.3-51.0 μm down to 2.61-2.95 μm, calculated using Equation 1:

$${d}_{p} = \sqrt{k / π {fc}_{v}} \qquad ( Equation 1 )$$

where k, f, and cᵥ are thermal conductivity, modulation frequency, and volumetric heat capacity, respectively. At lower frequencies, the larger dₚ increases sensitivity to the deeper interface (Gₐₗₙ/ₛᵢ) compared to the shallower interface (Gₐᵤ/ₐₗₙ), while the opposite trend can be observed at the higher frequencies.

### Scanning Electron Microscopy (SEM)

The ThermoFisher Apreo SEM was utilized in this study. An incident electron beam with an energy of 10 keV was employed. All images presented in this work are secondary electron images acquired using the Apreo's advanced in-lens detector.

### TEM

The ThermoFisher Talos G2 200× was employed in this experiment, operating at a beam energy of 200 kV and a beam current of 1 nA. Phase-contrast high-resolution images, in which all electron diffraction beams were collected by the objective lens, were recorded using a 4 k×4 k Ceta CMOS camera and subsequently analyzed with Gatan GMS 3.0 software.

### X-Ray Diffraction (XRD)

A parallel beam XRD optic was employed on the Rigaku SmartLab platform, equipped with a point detector mounted on the goniometer arm. The system used a Cu anode operating at 40 kV, producing X-rays with a wavelength of 0.154 nm. Conventional θ-2θ XRD scans were performed to determine the crystal phases. For the rocking curve measurements, the scan range was set from −5° to +5°, with the 2θ angle fixed at 36.0°, corresponding to the AlN (0002) reflection. Gaussian fitting in Origin 9.0 was used to analyze the FWHM of both the XRD and rocking curve peaks.

### X-Ray Photoemission Spectroscopy (XPS)

An ultra-high vacuum (UHV) chamber, manufactured by Omicron VT and equipped with an STAIB RQ-300 X-ray source (Mg anode, 1453.6 eV photon emission), was used for XPS measurements. Spectra were collected using a DESA 150 quadrupole electron analyzer at a 45° collection angle relative to the incident beam, with an energy resolution of 1 eV. Quantitative XPS analysis was carried out by Casa XPS software. RSF factor provided by Casa XPS software was utilized to calibrate the peak integration area and quantified the ratio between each element.

### Results and Discussion

The sustainment of reactive HiPIMS plasma at low working pressure was systematically investigated. Notably, plasma was ignited at 700 V with 1.8 Pa pure Ar condition at maximum frequency (2000 Hz) and then reduced to 540 V while adjusting the operating pressure and frequency to investigate the effect of frequency on plasma stability.

FIG. 1B illustrates graphs of target current (A) on the vertical axis plotted against time (μs) on the horizontal axis, showing the strong dependence of reactive HiPIMS plasma stability on the applied pulsing frequency. In this example, 1 sccm of N₂ was introduced into a 0.4 Pa Ar background. At a frequency of 2000 Hz, the waveform exhibits repeatable current spikes with uniform peak shapes and overlapping afterglow tails, confirming reproducible plasma with each pulse. A similar response is observed at 1900 Hz. However, when the frequency is reduced to 1800 Hz, the current transient drops fully to baseline between pulses, evidencing discharge extinction. This sharp transition arises from the threshold electron density required to sustain HiPIMS plasma at sub-Pascal pressure. At frequencies≥1900 Hz, the residual electron density between pulses remains sufficiently high to enable secondary electron emission and stabilize the discharge. In contrast, below 1900 Hz the extended off-time allows plasma decay, reducing the electron density below the critical level required for ionization, and the plasma collapses.

FIG. 1C illustrates graphs of target current (A) versus time (μs) at a working pressure of 0.7 Pa with 1 sccm of N₂. At 2000 Hz and 1750 Hz, the traces show stable and repeatable current peaks that retain a residual background current level between pulses, indicating continuous plasma sustainment. At 1500 Hz, however, the current waveform diminishes completely to baseline, confirming unstable operation and plasma extinction. Compared with FIG. 1B, the frequency threshold for sustaining the plasma decreases from ˜1900 Hz at 0.4 Pa to ˜1500 Hz at 0.7 Pa, consistent with longer plasma decay times and higher collisionality at elevated pressure. These results demonstrate that the maximum frequency capability of the HiPIMS system directly determines the lower pressure limit at which reactive HiPIMS deposition can be sustained.

FIG. 1D illustrates plots of discharge current (upper trace, arbitrary units) and applied voltage (lower trace, arbitrary units) versus time (μs) under high-frequency operation, used here to qualitatively explain the correlation between frequency and working pressure. HiPIMS plasma duty cycles typically range from 1% to 10%. Given that sputtering yield in reactive sputtering is generally lower than in metallic sputtering, the plasma density during the afterglow phase becomes key to maintaining stable HiPIMS plasma. In FIG. 1D, the current trace shows repeated peaks with minimal decay between pulses, while the voltage trace exhibits closely spaced rectangular pulses. This shortened interval between successive pulses maintains a higher residual plasma density and thereby sustains the secondary electron emission chain reaction.

FIG. 1E illustrates corresponding plots of discharge current (upper trace) and applied voltage (lower trace) versus time (μs) under low-frequency operation. In this case, the current trace decays more fully between pulses, and the voltage trace displays longer intervals between pulses. When the interval is prolonged in this manner, the plasma becomes too diluted during the afterglow to sustain the chain reaction, leading to unstable or extinguished HiPIMS plasma.

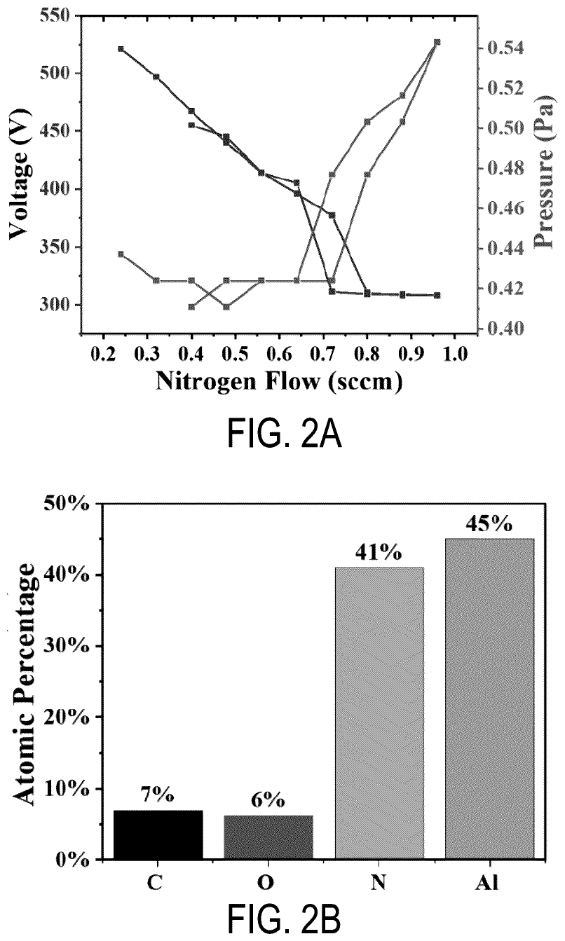

FIG. 2A illustrates the relationship between nitrogen flow rate (sccm, horizontal axis), target voltage (V, left vertical axis), and chamber pressure (Pa, right vertical axis) obtained from a DC hysteresis study using HiPIMS plus kick (bipolar HiPIMS). The plots show that as nitrogen flow increases, the target voltage decreases while chamber pressure rises. A disparity is observed between the hysteresis endpoints of voltage and pressure, which is attributed to differences in the spatial scale of measurement. Target voltage provides an instantaneous, surface-sensitive probe of the target state, whereas the pressure response represents a chamber-averaged measure of the reactive gas dynamics.

Based on this hysteresis study, AlN was deposited using HiPIMS plus kick (bipolar HiPIMS) with a 540 V main negative HiPIMS pulse (20 μs), a 40 V positive kick pulse (100 μs), and an N₂ plasma concentration of 26.8% at a total pressure of 0.5 Pa to examine the metal-to-nitrogen stoichiometry properties.

The endpoint of the hysteresis loop in FIG. 2A (corresponding to 0.88 sccm nitrogen flow) was employed for this deposition. Under these conditions, AlN adsorbates were assumed to cover the entire stage and chamber walls, maintaining a nitrogen-rich deposition atmosphere throughout sputtering.

FIG. 2B illustrates the resulting surface composition, showing 41% nitrogen, 6% oxygen, and 45% aluminum. These values indicate a charge-balanced ceramic compound, consistent with stoichiometric AlN deposition in the 26.8% N₂ environment.

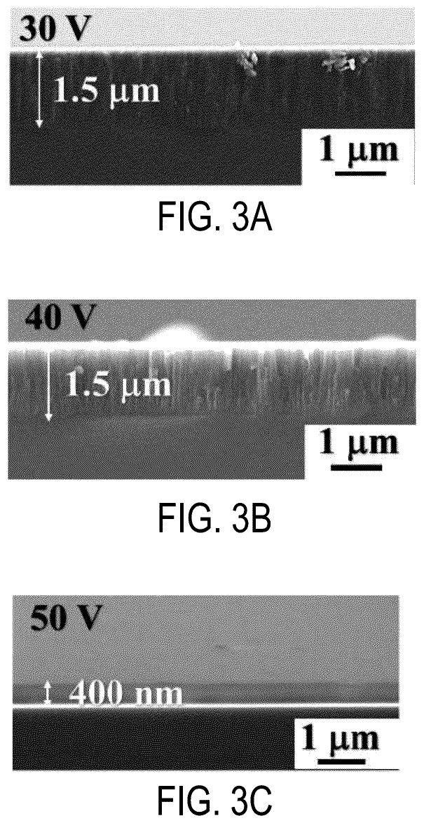

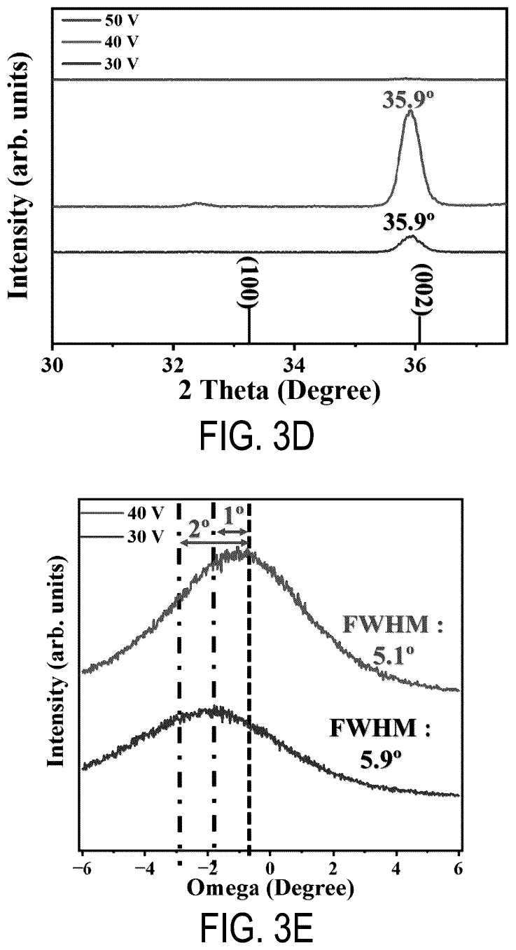

FIGS. 3A-3E collectively illustrate the influence of the positive “kick” voltage, applied during HiPIMS plus kick (bipolar HiPIMS) deposition, on the cross-section morphology and grain structure of AlN films. The figures demonstrate that the applied positive voltage strongly affects deposition rate, crystallinity, and microstructure.

FIG. 3A illustrates a cross-sectional SEM image of a film deposited with a 30 V positive kick voltage. The film exhibits a densely packed, vertically aligned columnar grain structure, with a thickness of approximately 1.5 μm.

FIG. 3B illustrates a cross-sectional SEM image of a film deposited with a 40 V positive kick voltage. Similar to the 30 V condition, the film shows a densely packed columnar structure with a thickness of approximately 1.5 μm.

FIG. 3C illustrates a cross-sectional SEM image of a film deposited with a 50 V positive kick voltage. At this condition, the deposition rate decreased by about 75% compared to the 40 V case, resulting in a significantly reduced thickness of approximately 400 nm. The loss of deposition efficiency and altered morphology indicate substantial modification of growth dynamics under higher positive kick voltages.

FIG. 3D illustrates X-ray diffraction (XRD) patterns of films deposited with 30 V, 40 V, and 50 V positive kick voltages. Distinct (002) diffraction peaks are present for the 30 V and 40 V films, confirming c-axis oriented AlN crystallinity. In contrast, the (002) peak is absent for the 50 V film, demonstrating that the film is amorphous under this condition. The amorphization is attributed to plasma resputtering caused by the energetic positive kick pulse. Considering that the bond dissociation energy of AlN is approximately 2.74 eV, ions with kinetic energies on the order of 50 eV have sufficient momentum to displace surface AlN species during deposition, thereby disrupting crystal growth.

FIG. 3E illustrates omega rocking curves for films deposited with 30 V and 40 V positive kick voltages. The FWHM of the rocking curve is approximately 5.9° for the 30 V film and 5.1° for the 40 V film, indicating improved crystallinity at 40 V. The data confirm that moderate positive kick voltages promote film crystallization even at a substrate temperature of about 120° C., while excessive positive voltages, such as 50 V, induce resputtering that reduces deposition rate and degrades crystallinity.

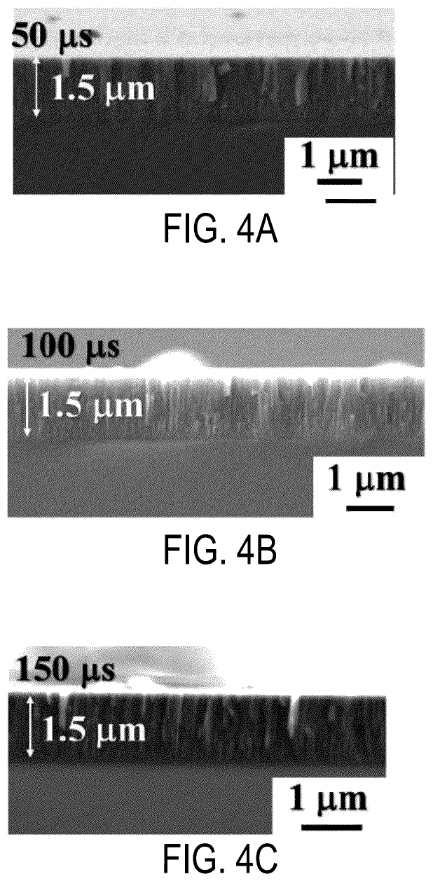

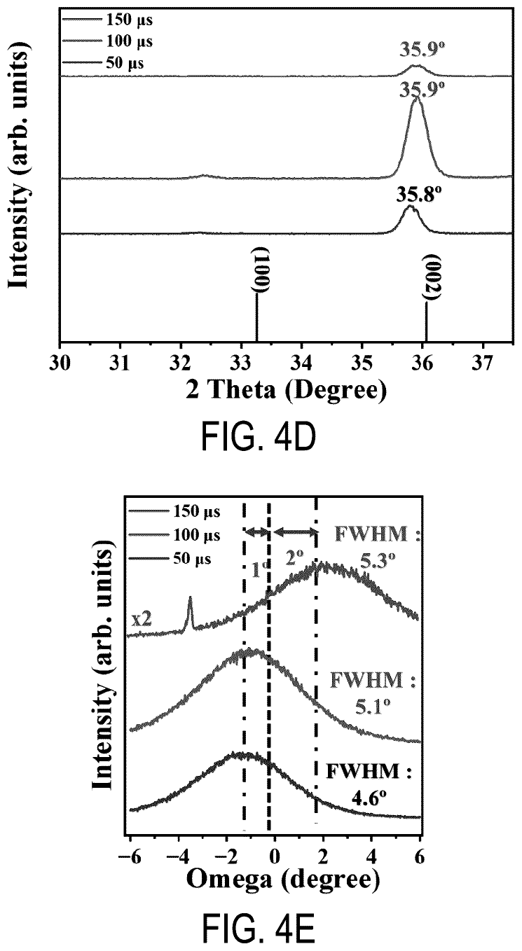

FIGS. 4A-4E collectively illustrate the influence of positive kick pulse width in HiPIMS plus kick (bipolar HiPIMS) deposition on the structure and crystallinity of AlN films. The results indicate that varying the duration of the positive kick pulse impacts film morphology, diffraction peak intensity, and rocking curve characteristics.

FIGS. 4A-4C illustrate cross-sectional SEM images of AlN films deposited with positive kick pulse widths of 50 μs, 100 μs, and 150 μs, respectively. In each case, the films exhibit comparable columnar grain structures with thicknesses of approximately 1.5 μm.

FIG. 4D illustrates X-ray diffraction (XRD) spectra showing the XRD (002) diffraction peaks for the same films. The diffraction peak positions are located at approximately 35.8° for the 50 μs deposition, 35.9° for the 100 μs deposition, and 35.9° for the 150 μs deposition. The relative intensities of the peaks differ among the three samples, with the 100 μs condition exhibiting the strongest (002) intensity.

FIG. 4E illustrates omega rocking curve scans of the same films. The rocking curves show measurable peak offsets, attributed to argon incorporation during deposition. The 150 μs deposition exhibits a peak offset of approximately 2°, while the 50 μs and 100 μs depositions show smaller offsets of about 1°. The corresponding FWHM values are approximately 4.6° for the 50 μs film, 5.1° for the 100 μs film, and 5.3° for the 150 μs film. Because the intensity of the XRD (002) diffraction peak in FIG. 4D corresponds to the rocking curve intensity at Omega=0°, these offsets directly influence the apparent diffraction peak intensities.

These results indicate that extending the positive kick pulse to 150 μs increases the orientation mismatch between the Si(100) substrate texture and the AlN (002) film texture. This mismatch is attributed to a reduction in the Al³⁺/Al ion ratio in the HiPIMS plasma during the extended positive pulse.

The rocking curve profiles for the 50 μs and 100 μs depositions are similar in overall shape, but the XRD (002) diffraction intensity is higher for the 100 μs condition. This demonstrates a limitation of rocking curve analysis, as such scans probe only a single out-of-plane crystallographic direction and therefore do not fully capture variations in overall crystalline quality.

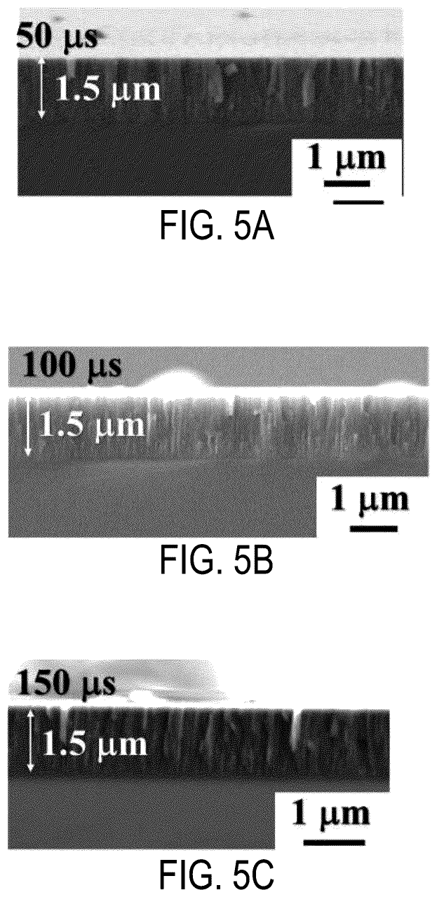

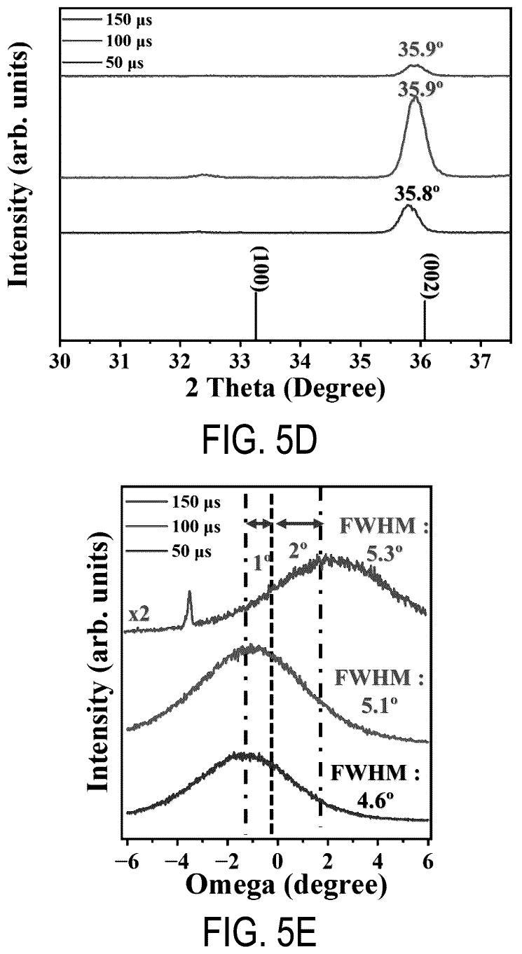

FIGS. 5A-5E collectively illustrate the effect of HiPIMS main negative pulse width on AlN film morphology and crystallinity, under conditions of a 40 V positive kick with 100 μs duration.

FIGS. 5A-5C illustrate cross-sectional SEM images of AlN films deposited with main negative pulse widths of 15 μs, 20 μs, and 25 μs, respectively. The films deposited with 15 μs and 20 μs main pulses exhibit comparable columnar grain structures with film thicknesses of approximately 1.5 μm. In contrast, the 25 μs sample shows the presence of large surface droplets, as observed in FIG. 5C, consistent with arcing or localized overheating at the target surface.

FIG. 5D illustrates X-ray diffraction (XRD) spectra of the same films, showing the XRD (002) diffraction peaks. The diffraction peak positions are approximately 35.8° for the 15 μs deposition, 35.9° for the 20 μs deposition, and 35.9° for the 25 μs deposition. The 20 μs condition exhibits the strongest (002) peak intensity, consistent with enhanced crystalline alignment.

FIG. 5E illustrates omega rocking curve scans of the same films. The rocking curve FWHM is approximately 4.6° for the 15 μs film, 3.9° for the 20 μs film, and 5.3° for the 25 μs film. Thus, the 20 μs deposition shows a 0.7° narrower FWHM compared to the 15 μs film, indicating improved crystallinity. The rocking curve peak for the 20 μs deposition also shows only a 1° offset, compared to a 3.5° offset for the 15 μs film and a 2° offset for the 25 μs film. These results demonstrate significantly improved uniaxial grain orientation for the 20 μs deposition.

Collectively, the SEM, XRD, and rocking curve data indicate that a main negative pulse width of approximately 20 μs yields superior AlN film quality under the tested conditions. Shorter pulse widths result in reduced crystallinity, while extended widths promote droplet formation due to arcing.

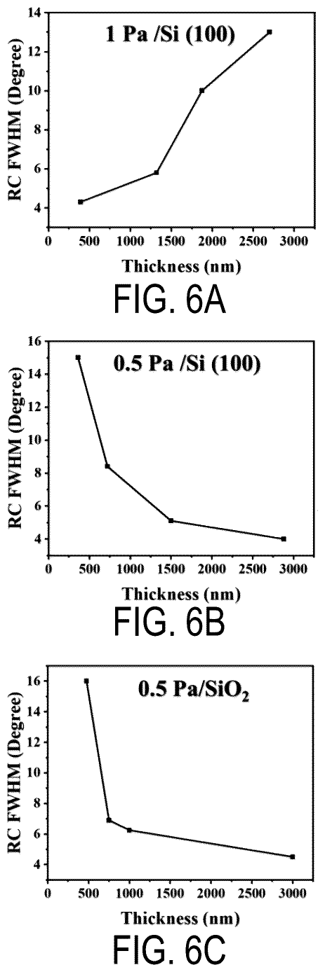

FIGS. 6A and 6B illustrate the FWHM of the omega rocking curve (RC) as a function of film thickness for AlN films deposited on Si(100) substrates at working pressures of 1.0 Pa and 0.5 Pa, respectively.

In FIG. 6A, corresponding to deposition at 1.0 Pa, the RC FWHM increases monotonically with increasing film thickness, reaching values above 12° at a thickness of approximately 3000 nm. This grain evolution behavior contrasts with conventional expectations, where thicker AlN films often exhibit reduced FWHM due to improved crystallinity. The observed increase at 1.0 Pa is attributed to the reduced mean free path of sputtered species under elevated pressure. In this regime, the positive kick pulse establishes a sheath potential that accelerates ions uniformly with energies closely following the kick bias. However, collisions between energetic species and background neutrals dominate the transport process, limiting the transfer of energy to the growing film surface. As a result, grain coalescence is hindered and crystallinity degrades with increasing thickness.

In FIG. 6B, corresponding to deposition at 0.5 Pa, the RC FWHM decreases monotonically with increasing film thickness, falling from approximately 14° at 500 nm to below 5° at 3000 nm. This trend indicates progressive alignment of AlN grains as thickness increases, a behavior attributed to grain coalescence and enhanced texture development under low-pressure conditions. The extended mean free path at 0.5 Pa facilitates efficient energy transfer from ions to the growing film, thereby promoting grain orientation and improved crystallinity.

Collectively, the results demonstrate that low-pressure deposition (0.5 Pa) can be more favorable than higher-pressure deposition (e.g., 1.0 Pa or higher) for achieving high-quality thick AlN films with narrower rocking curve widths and enhanced crystalline alignment.

FIG. 6C illustrates the evolution of the rocking curve (RC) FWHM as a function of thickness for AlN films deposited on an amorphous SiO₂ layer supported by a Si substrate at a working pressure of 0.5 Pa.

The deposition conditions in FIG. 6C were the same as those used for the Si(100) substrate in FIG. 6B. At an early stage of growth, corresponding to approximately 390 nm of thickness, the AlN film exhibited an RC FWHM of about 16°, similar to the value observed for deposition on the crystalline Si(100) substrate. As the thickness increased, the RC FWHM gradually decreased. This monotonic decrease with thickness was consistent with the behavior observed on the crystalline Si(100) substrate. For a film thickness of approximately 3 μm on SiO₂, the RC FWHM was measured at about 4°, comparable to the value obtained for a film of the same thickness on a Si(100) substrate.

This comparison indicates that HiPIMS plus kick (bipolar HiPIMS) AlN deposition at a working pressure of 0.5 Pa can produce films with similar crystalline alignment on both amorphous and crystalline substrates. The results suggest that grain orientation is influenced primarily by the deposition process rather than the crystallinity of the underlying substrate, with the low-pressure condition providing sufficient adatom mobility for c-axis alignment.

These findings further indicate that HiPIMS plus kick (bipolar HiPIMS) AlN deposition may be applicable to semiconductor backend-of-line integration, where films are often deposited on amorphous low-k SiCOH dielectric materials. In addition, the experiment on dielectric SiO₂ indicates that the positive kick pulse establishes the sheath potential without dependence on substrate conductivity, in contrast to conventional DC substrate bias approaches.

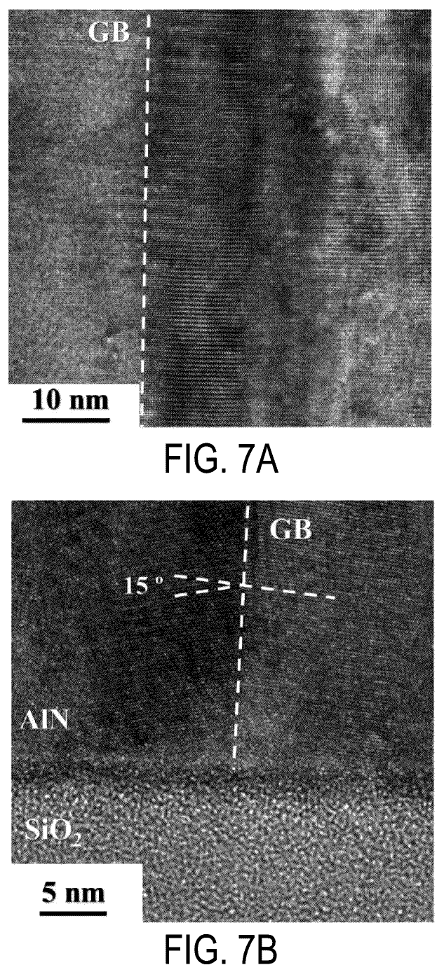

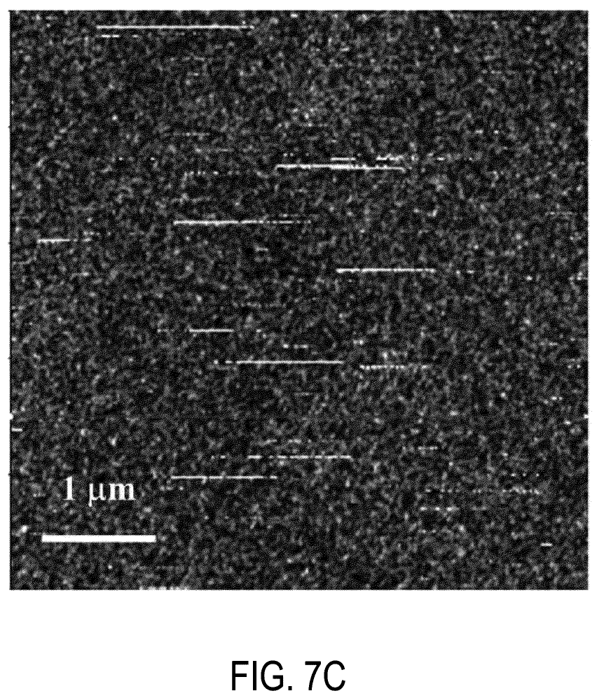

FIG. 7A illustrates a high-resolution transmission electron microscopy (HRTEM) image of the grain structure of a 1.5 μm-thick bulk AlN film deposited via low-pressure HiPIMS plus kick (bipolar HiPIMS). The figure highlights the region near a grain boundary. In the out-of-plane direction, distinct lattice fringes with a spacing of approximately 0.26 nm are observed, confirming the strong c-axis orientation of the AlN film and indicating preferential growth along this crystallographic axis.

The image shows that the lattice fringes in adjacent grains display slight mismatches, indicating misalignment along different zone axes under identical imaging conditions. Notwithstanding these differences, the fringes exhibit continuity across the horizontal direction at the grain boundary. This continuity suggests minimal displacement or misfit between neighboring grains, even when their orientations differ. Such structural coherence across the boundary is indicative of effective atomic-scale accommodation during growth.

This behavior is attributed to enhanced ion mobility during deposition, enabled by the positive kick pulse in conjunction with the dense plasma environment of HiPIMS plus kick (bipolar HiPIMS). The positive kick pulse sustains a high flux of energetic species, facilitating intergranular diffusion and structural ordering at low substrate temperatures.

The results indicate that sputtered Al ions, as well as Ar⁺ ions, with an incident momentum of approximately 40 eV, supply adatoms with sufficient energy to overcome diffusion activation barriers at grain boundaries. These energetic species promote the migration of adatoms to energetically favorable lattice positions, thereby enabling the formation of a continuous atomic structure across grain interfaces. The resulting grain boundary coherence contributes to the overall crystalline quality and thermal transport performance of the AlN film.

FIG. 7B illustrates the interface between crystalline AlN and amorphous SiO₂. An interfacial layer approximately 0.5 nm thick is visible, which results from intermixing of AlN and SiO₂ induced by Ar⁺ and Al ion bombardment during the initial stages of sputtering. Although it is generally assumed that the initial tens of nanometers of a sputtered film deposited on an amorphous substrate would remain amorphous, the HiPIMS plus kick (bipolar HiPIMS) process facilitated the immediate crystallization of AlN, forming large grains on the order of 10 nm in size.

The micrograph shows that the AlN grains exhibit an angular misorientation of approximately 15° between adjacent grains. Despite this misorientation, the AlN crystallized almost immediately following the formation of the thin intermixing layer, establishing a coherent crystalline structure above the amorphous base.

The presence of this thin intermixing layer may be considered advantageous, as it may be expected to reduce thermal boundary resistance when AlN is deposited on commercially relevant low-k SiCOH interconnect materials. The ability of the HiPIMS plus kick (bipolar HiPIMS) process to promote such early-stage crystallization directly on amorphous substrates demonstrates its suitability for backend-of-line integration in semiconductor device fabrication.

The surface morphology analysis, performed using atomic force microscopy (AFM), further supports the role of ion bombardment in improving film quality.

FIG. 7C is an atomic force microscopy (AFM) image of an aluminum nitride thin film deposited using high power impulse magnetron sputtering combined with a positive voltage pulse. The AFM image corresponds to a film having a thickness of about 600 nm deposited at a substrate temperature of about 120° C. under conditions of a 540 V HiPIMS pulse and a 100 μs positive kick pulse. The surface scan over a 5 μm by 5 μm area shows a root mean square roughness on the order of about 0.5 to 0.6 nm, indicating an extremely smooth film surface. This smooth morphology is attributed to enhanced surface adatom mobility induced by the positive voltage pulse, which energizes plasma ions and promotes surface diffusion during film growth. The low surface roughness supports improved film quality by suppressing cluster and agglomerate formation.

As shown in FIG. 7C, a sub-nanometer roughness was observed for a 600 nm HiPIMS plus kick (bipolar HiPIMS) AlN film (Root Mean Square roughness=0.6 nm) for a target substrate distance of 7 cm. This low roughness is attributed to a high surface diffusion rate, which inhibits cluster or agglomerate formation. The AFM analysis highlights the importance of the positive kick voltage in energizing plasma ions, thereby enhancing surface adatom mobility during the film deposition process.

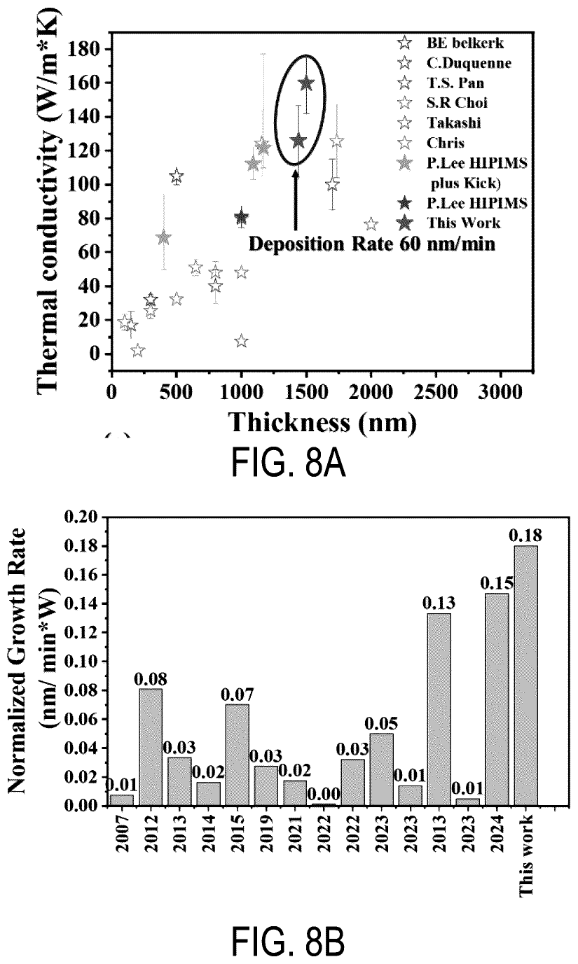

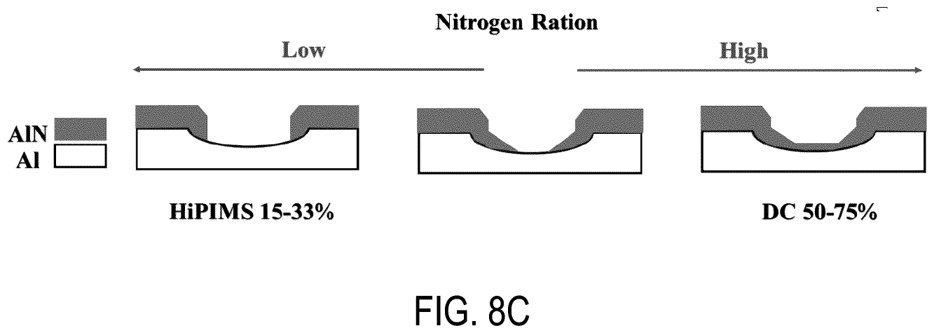

FIG. 8A illustrates a comparison of the room-temperature cross-plane thermal conductivity of AlN films deposited by HiPIMS plus kick (bipolar HiPIMS) (shown as filled star symbols) with values reported in the literature (shown as unfilled star symbols). The cross plane thermal conductivity values were measured by frequency-domain thermoreflectance (FDTR). Error bars represent uncertainty calculated using a Monte Carlo method. Table 2 summarizes deposition conditions from the literature together with the present HiPIMS plus kick (bipolar HiPIMS) study, including substrate temperature, working pressure, applied power normalized to target size, and target-to-substrate distance.

TABLE 2

| | | | | | | | | This |
|---|---|---|---|---|---|---|---|---|
| | B. E. | | | | | | Ping¹⁸ | work |
| | Belkerk ³⁶^{_{—}}³⁷ | C Duquenne ¹⁴ | Pan ¹³ | Choi ¹⁵ | Yagi ¹⁶ | Perez, ¹⁷ | HiPIMS | HiPIMS |
| | Unbalanced | Unbalanced | Balanced RF | RF | RF | DC | plus kick | plus kick |
| Technique | DC sputter | DC sputter | sputter | sputter | sputter | sputter | sputter | sputter |
| Pressure (Pa) | 0.4 | 0.3 | 0.3 | unknown | 0.7 | 0.4 | 1 | 0.53 |
| Power (W/cm²) | 7.64 | 7.64 | 101.88 | 55.28 | 6.56 | 5.08 | 8.37 | 16.3 |
| Temperature (° C.) | 20 | 300 | 400 | 20 | 20 | 20 | 180 | 120 |
| Target to | 3 | 3 | unknown | unknown | unknown | 7 | 7 | 7 |
| substrate | | | | | | | | |
| distance (cm) | | | | | | | | |

The thermal conductivities of AlN films—deposited on silicon (100) substrates using a 540 V HiPIMS pulse with a 100 μs, 40 V positive kick at 120° C. for a 90-minute deposition, as shown by the filled red stars in FIG. 8A—were measured with FDTR to evaluate the suitability of this method for heat spreader applications. The thermal conductivities of the two films were 125.9 (+20.7/−21.6) W/m·K and 159.9 (+16.7/−18.5) W/m·K, respectively. The latter value represents one of the highest reported thermal conductivities for AlN films of similar thickness.

Moreover, the deposition rate in the present low-pressure HiPIMS plus kick (bipolar HiPIMS) study (60 nm/min) is significantly higher compared to high-pressure HiPIMS plus kick (bipolar HiPIMS) (30 nm/min) and DC sputtering (5 nm/min), while achieving similar thermal conductivities. This twofold increase in deposition rate, relative to previous HiPIMS studies, is attributed to variations in the mean free path of plasma molecules and the degree of target poisoning. At a pressure of 1.0 Pa, nitrogen molecules with a radius of approximately 300 μm have a mean free path of 0.9 cm, whereas at 0.5 Pa, the mean free path extends to 1.8 cm. Given that the substrate-to-target distance in this study is 7 cm, the number of ion collisions during deposition is reduced by half. This reduction not only doubles the deposition rate but also increases the average momentum of incident ions, enabling high film quality to be maintained while simultaneously achieving a high deposition rate.

FIG. 8B illustrates normalized growth rates of AlN films reported in the literature compared with the present HiPIMS plus kick (bipolar HiPIMS) study. The low-pressure HiPIMS plus kick (bipolar HiPIMS) process achieved a normalized deposition rate of 0.18 nm·W⁻¹·min⁻¹, representing nearly a 100% increase over the fastest reported DC sputtering rate of 0.08 nm·W⁻¹·min⁻¹, and a 17% increase compared to high-pressure HiPIMS plus kick (bipolar HiPIMS) (0.15 nm·W⁻¹·min⁻¹) and monopolar low-pressure (0.4 Pa) HiPIMS (0.13 nm·W⁻¹·min⁻¹). Under the same configuration, DC sputtering (similar chamber size and cathode) produced a deposition rate of 25 nm/min at 400 W for a 2″ diameter target, corresponding to a normalized rate of 0.06 nm·W⁻¹·min⁻¹. These comparisons confirm that the enhanced deposition rate in the present work cannot be explained by power normalization alone. In addition to mean free path effects, differences in the degree of target poisoning play a central role. For example, monopolar HiPIMS used 35% N₂ at a repetition frequency of 300 Hz, whereas the present HiPIMS plus kick (bipolar HiPIMS) study used 25% N₂ at 2000 Hz. Because power normalization has already been accounted for in FIG. 8B, the target condition remains the primary differentiating factor, as further illustrated schematically in FIG. 8C.

FIG. 8C schematically depicts the influence of nitrogen fraction on target poisoning in HiPIMS and DC sputtering. By combining a lower nitrogen fraction for stoichiometric AlN formation with the advantages of low-pressure operation, HiPIMS achieved the highest reported AlN sputter deposition rate while maintaining the film's thermal properties. In contrast, DC sputtering continuously removes material from the target, but the formation of an AlN compound layer on the Al target surface significantly reduces the effective sputter yield. The DC sputtering study in FIG. 8B was operated in the deep-poisoning mode of the hysteresis loop to ensure film quality, whereas HiPIMS was maintained in the transition regime. Operation in the transition regime allowed HiPIMS to sustain higher instantaneous sputtering rates and thereby achieve higher overall growth rates compared to DC sputtering.

The present disclosure demonstrates that HiPIMS plus kick (bipolar HiPIMS) operated at working pressures below 0.5 Pa enables high-rate deposition of AlN films. A deposition rate of 60 nm/min (0.18 nm·W⁻¹·min⁻¹) for a target substrate distance of 7 cm was obtained for AlN films exhibiting single-texture growth on both lattice-mismatched Si(100) and on 1 μm amorphous SiO₂/Si substrates. The resulting films exhibited thermal conductivities comparable to previously reported values. The foregoing description sets forth process optimization strategies, underlying physical mechanisms, and the advantages associated with HiPIMS plus kick (bipolar HiPIMS) at 0.5 Pa.

A comparison with HiPIMS plus kick (bipolar HiPIMS) at 1.0 Pa confirms the benefits of low-pressure deposition, where reduced argon gas collisions promote improved grain structure formation. Depositions on SiO₂ substrates further establish that electrical conductivity and substrate crystal structure exert negligible influence on the resulting film quality. Frequency-domain thermoreflectance (FDTR) measurements indicated that HiPIMS plus kick (bipolar HiPIMS) AlN films exhibited thermal conductivities in the range of 120-160 W/m·K, with deposition rates up to 60 nm/min. These results demonstrate performance that exceeds other sputtering techniques employed for high-thermal-conductivity AlN deposition.

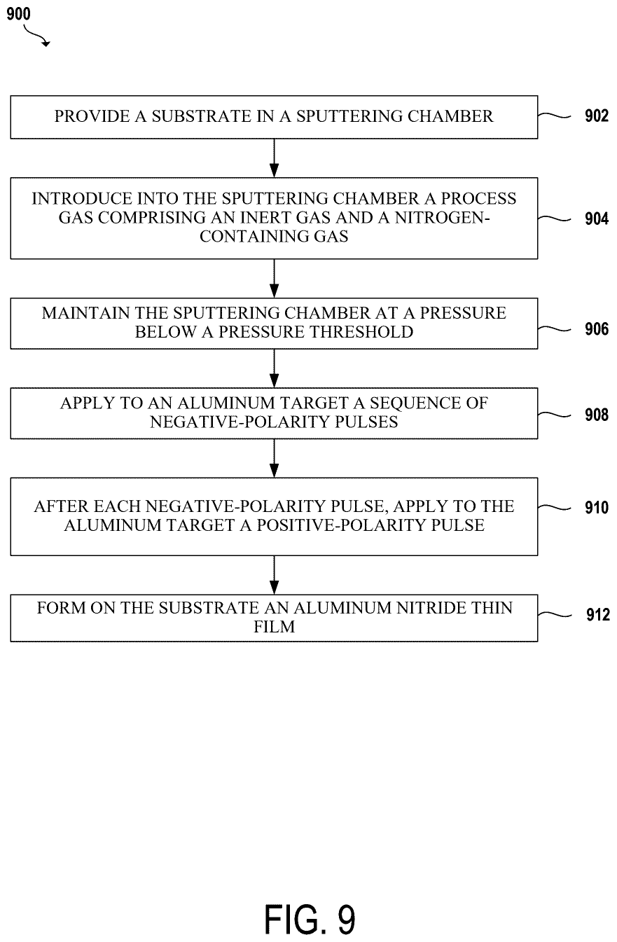

FIG. 9 is a flow diagram illustrative of an embodiment of a routine 900 for depositing an aluminum nitride thin film using sputtering. Although described herein with reference to particular process parameters and sequences, it will be understood that the elements outlined for routine 900 can be implemented in any one or a combination of sputtering systems configured to deposit aluminum nitride films. Thus, the following illustrative embodiment should not be construed as limiting.

At block 902, a substrate can be provided in a sputtering chamber. The substrate can include, such as, but not limited to, silicon (e.g., Si(100) or Si(111)), sapphire, silicon carbide, or gallium nitride. In some cases, the substrate can also include an amorphous material, such as, but not limited to, SiO₂, glass, or quartz, thereby enabling integration of the deposited aluminum nitride thin film with backend-of-line semiconductor or optoelectronic devices. Providing the substrate can enable integration of the deposited aluminum nitride thin film with semiconductor or optoelectronic devices. The substrate can be positioned on a support that can control substrate temperature during deposition. The substrate temperature can be maintained within a range from approximately room temperature to about 500° C. In some embodiments, the substrate can be actively cooled so that aluminum nitride thin films can be deposited with high crystallinity and thermal conductivity at reduced thermal budgets.

In some cases, a sputtering system can be configured so that, once the deposition process is initiated, the substrate can be rotated or biased. Providing the substrate in this manner can allow subsequent process steps to achieve aluminum nitride films with uniform thickness, reduced stress, and controlled crystallographic orientation. In some cases, the substrate can be introduced after the sputtering chamber has been evacuated to a base pressure, such as, but not limited to, 10⁻⁴ to 10⁻⁷ Torr. Providing the substrate under these conditions can reduce contamination and allow subsequent steps to form aluminum nitride films with high thermal conductivity.

At block 904, a process gas can be introduced into the sputtering chamber. The process gas can include an inert gas and a nitrogen-containing gas. The inert gas can include, such as, but not limited to, argon, neon, krypton, xenon, or helium. The nitrogen-containing gas can include, such as, but not limited to, molecular nitrogen (N₂), ammonia (NH₃), nitrogen oxides (NO, NO₂), hydrazine (N₂H₄), or mixtures thereof.

The nitrogen-containing gas can be provided as a proportion of the total process gas flow within a range from about 5% to about 70%, such as within narrower ranges from about 10% to about 50%, or from about 15% to about 40%. In some cases, the nitrogen-containing gas can include about 25% to about 27% of the total process gas flow (e.g., about 26.8%). Introducing the process gas with the nitrogen content within these ranges promotes reactive sputtering of aluminum nitride while avoiding target poisoning and maintaining plasma stability. In some cases, the introduction of the process gas in this manner allows subsequent application of negative-polarity voltage pulses and positive-polarity voltage pulses to form aluminum nitride thin films having controlled crystallinity, orientation, and thermal conductivity. The nitrogen-containing gas can be introduced in an amount sufficient to deposit stoichiometric aluminum nitride while avoiding target poisoning of the aluminum target, including operation of the aluminum target in a transition regime between a metallic state and a poisoned state.

At block 906, the sputtering chamber can be maintained to satisfy a pressure threshold. Satisfying the pressure threshold can include, but is not limited to, maintaining the pressure below about 10 Pa, below about 5 Pa, below about 4 Pa, below about 3 Pa, below about 2 Pa, below about 1 Pa, below about 0.8 Pa, below about 0.6 Pa, below about 0.5 Pa, or below about 0.3 Pa. In some cases, satisfying the pressure threshold can include controlling the pressure within ranges such as from about 0.05 Pa to about 4.5 Pa, from about 0.05 Pa to about 3.5 Pa, from about 0.05 Pa to about 2.5 Pa, from about 0.05 Pa to about 1.5 Pa, from about 0.05 Pa to about 0.9 Pa, from about 0.1 Pa to about 0.8 Pa, from about 0.1 Pa to about 0.3 Pa, or from about 0.15 Pa to about 0.25 Pa. In some cases, the pressure can be maintained between about 0.4 Pa and about 0.5 Pa.

Maintaining the pressure can include holding the chamber pressure substantially constant during deposition, dynamically adjusting the chamber pressure within these thresholds and ranges, or controlling partial pressures of the inert and nitrogen-containing gases. Maintaining the pressure can include regulating pumping speed, throttle valve position, or process gas flow, and can be applied during ignition of the plasma, during application of negative-polarity voltage pulses and/or positive-polarity voltage pulses, or throughout the entire deposition period. The chamber can first be evacuated to a base pressure, such as 10⁻⁴ to 10⁻⁷ Torr, before process gas introduction.

In some cases, maintaining the chamber pressure to satisfy the pressure threshold can increase mean free path, reduce scattering, thereby enabling stable reactive sputtering and deposition of aluminum nitride thin films having improved crystallinity, c-axis orientation, and thermal conductivity.

At block 908, a sequence of negative-polarity voltage pulses is applied to an aluminum target. The sequence of negative-polarity voltage pulses can be high power impulse magnetron sputtering (HiPIMS) pulses characterized by short pulse durations and high peak powers relative to conventional direct current sputtering.

As described herein, the term “negative-polarity voltage pulse” can refer to a transient application of a voltage that is below the plasma potential or ground potential, such as a negative bias applied to the aluminum target, and can include voltages having a magnitude sufficient to establish a cathodic potential that accelerates ions toward the target. The negative-polarity voltage pulse can be more negative than 0 V, or can be referenced relative to the plasma potential, and can range in magnitude from several volts to several hundred volts depending on process conditions. The negative-polarity voltage pulse can be generated by any pulsed power source capable of delivering high instantaneous power, including impulse, bipolar, or asymmetric pulse waveforms. The negative-polarity voltage pulse can exhibit a microsecond-scale pulse width, a repetition frequency sufficient to sustain residual plasma between pulses, and a peak current and/or peak power greater than that of steady-state direct current sputtering. The negative-polarity voltage pulse can ionize a significant portion of sputtered aluminum species, increase plasma density, and promote directional transport of ionized species toward the substrate to enhance film densification, crystallographic orientation, and overall film quality.

The negative-polarity voltage pulses can have a pulse duration within a range from about 10 μs to about 500 μs, from about 20 μs to about 300 μs, or from about 50 μs to about 200 μs. In some cases, the pulse duration is between about 10 μs and about 25 μs. The pulse frequency can be within a range from about 10 Hz to about 5000 Hz, from about 50 Hz to about 1000 Hz, or from about 100 Hz to about 500 Hz. In some cases, the pulse frequency is at least about 1900 Hz. The duty cycle can be less than about 10%, such as less than about 5% or less than about 2%. In some embodiments, the sequence of negative-polarity voltage pulses has a pulse width of less than about 50 μs at a repetition frequency of at least about 1000 Hz, and a positive-polarity voltage pulse follows each negative-polarity voltage pulse with an amplitude of at least about 20 V and a duration of at least about 20 μs.

The sequence of negative-polarity voltage pulses can comprise any number of pulses sufficient to deposit an aluminum nitride thin film of desired thickness, such as from about 10³ pulses to about 10⁷ pulses, from about 10⁴ pulses to about 10⁶ pulses, or from about 10⁵ pulses to about 5×10⁵ pulses. The number of pulses can correspond to deposition times ranging from several seconds to several hours, depending on the targeted film thickness and deposition rate.

Applying the negative-polarity voltage pulses to the aluminum target in this manner can ionize a significant fraction of the sputtered aluminum species and can generate a dense plasma within the sputtering chamber. The ionization fraction of aluminum during application of the negative-polarity voltage pulses can exceed 20%, 40%, 60%, or 80%, thereby promoting directional transport of aluminum ions toward the substrate and enhancing the growth of aluminum nitride thin films with controlled crystallinity, c-axis orientation, and improved thermal conductivity.

At block 910, a positive-polarity voltage pulse can be applied to the aluminum target following the negative-polarity voltage pulses. The positive-polarity voltage pulse can be applied directly after, or with a controlled delay relative to, each negative-polarity voltage pulse to modify plasma conditions and control transport of ionized species. In some cases, the positive-polarity voltage pulse can be applied within about 10 μs after termination of each negative-polarity voltage pulse.

As described herein, the term “positive-polarity voltage pulse” can refer to a transient application of an electrical bias that produces a potential on the aluminum target that is above the plasma potential or ground potential. The positive-polarity pulse can be implemented as a voltage pulse, a current-controlled pulse, a power-regulated pulse, or any electrical excitation that results in a net positive potential on the target. The positive-polarity pulse can have a magnitude sufficient to repel electrons, attract negatively charged ions, and modify the plasma sheath near the target. The positive-polarity pulse can be slightly above 0 V or can be significantly higher in magnitude, depending on process conditions, and can be referenced relative to ground potential or plasma potential. In some cases, the positive-polarity pulse can be applied within about 10 μs after termination of each negative-polarity voltage pulse.

The positive-polarity voltage pulse (sometimes referred to as a “positive kick voltage”) can have an amplitude within a range from about +10 V to about +500 V, such as +20 V to +400 V, +50 V to +300 V, or +100 V to +250 V. In some cases, the amplitude can be between about +30 V and about +50 V. The pulse duration can be within a range from about 1 μs to about 500 μs, from about 5 μs to about 200 μs, or from about 10 μs to about 100 μs. In some cases, the pulse duration can be between about 50 μs and about 150 μs. The positive-polarity voltage pulse can be applied after every negative-polarity voltage pulse, after every second or third negative-polarity voltage pulse, or in a periodic sequence of pulses. The positive-polarity voltage pulse amplitude can be held substantially constant during deposition or can be varied over time—such as per pulse, per burst, or per deposition stage-by step-wise, ramped, or modulated control within the identified ranges, and the positive-polarity voltage pulse duration can likewise be held substantially constant or varied over time within the identified ranges.

Application of the positive voltage pulse can draw back negatively charged ions and electrons from the plasma, reduce charge accumulation, and stabilize reactive sputtering conditions. The positive-polarity voltage pulse can further promote transport of aluminum and nitrogen species toward the substrate in a more controlled manner, enhancing plasma uniformity and enabling deposition of aluminum nitride thin films having improved crystallinity, reduced stress, smoother surfaces, and higher thermal conductivity. In some cases, increasing the positive-polarity voltage pulse amplitude to about +50 V can reduce deposition rate and can lead to loss of texture or amorphization under otherwise similar conditions.

At block 912, an aluminum nitride thin film can be formed on the substrate. In some cases, formation of the aluminum nitride thin film can be a direct result of carrying out the preceding steps of introducing the process gas, maintaining the chamber pressure, and applying negative-polarity voltage pulses followed by positive-polarity voltage pulses, without requiring a separate active step. In other cases, the formation can be considered an active step of depositing material onto the substrate surface.

The aluminum nitride thin film can comprise a c-axis crystallographic texture and can exhibit a rocking curve FWHM at the (0002) reflection of less than about 3.0°, less than about 2.0°, less than about 1.5°, or less than about 1.0°. The film can have a cross plane thermal conductivity of at least about 100 W/m·K, at least about 120 W/m·K, at least about 140 W/m·K, at least about 150 W/m·K, or up to about 160 W/m·K. The deposition rate can be greater than about 20 nm/min, greater than about 40 nm/min, or up to about 60 nm/min. In some cases, the deposition rate can be at least about 60 nm/min. The film thickness can range from about 50 nm to about 5 μm, such as from about 100 nm to about 2 μm. The surface roughness can be less than about 5 nm RMS, less than about 3 nm RMS, about 1-2 nm RMS, or less than about 0.5 nm RMS.

Formation of the aluminum nitride thin film in this manner can provide a dense, highly oriented, and thermally conductive layer suitable for semiconductor, power electronic, and optoelectronic device integration.

### Terminology

As used herein, the term “film” or “thin film” can refer to a deposited layer of material having a thickness less than about one millimeter. In some embodiments, it can refer to a deposited layer of material having a thickness less than about 800 μm, 600 μm, 500 μm, 400 μm, 200 μm, or 100 μm or within the nanometer to micrometer range. An “aluminum nitride film” or “AlN film” can refer to a layer that includes aluminum nitride formed on a substrate by sputter deposition, pulsed sputtering, chemical vapor deposition, or other suitable thin-film deposition processes. A film can be referred to as a “coating,” “layer,” or “deposited layer,” and such terms can be understood interchangeably.

The term “sputtering” can refer broadly to physical vapor deposition involving the ejection of material from a target under ion bombardment. The term “magnetron sputtering” can refer to any configuration in which magnetic fields are used to confine electrons near the target, and can include balanced or unbalanced magnetron arrangements, planar or cylindrical targets, or direct current (DC), pulsed DC, mid-frequency (MF), or radio-frequency (RF) excitation. “High-power impulse magnetron sputtering” (HiPIMS) can refer to a pulsed sputtering process with relatively high peak power densities and relatively low duty cycles, although other pulsed modes can also be employed. A “negative-polarity voltage pulse” or “negative-polarity pulse” can refer to a transient application of an electrical bias that drives the target to a potential below the plasma potential or ground potential, and can include voltage-controlled, current-controlled, or power-regulated pulses that sputter material from the target. A “positive-polarity voltage pulse,” “positive pulse,” “positive kick,” “reverse pulse,” or “post-pulse bias” can refer to a transient application of an electrical bias that drives the target to a potential above the plasma potential or ground potential, and can include equivalent biasing schemes such as voltage pulses, current-controlled pulses, power-regulated pulses, bipolar pulsing, or substrate bias modulation.

The term “substrate” can refer to a wide variety of underlying materials including, but not limited to, semiconductor wafers (e.g., silicon, silicon carbide, gallium nitride), insulating substrates (e.g., quartz, glass, sapphire, silicon dioxide), metallic substrates (e.g., copper, aluminum, stainless steel), or combinations thereof. The substrate can be at least one of Si(100), Si(111), SiO₂, or sapphire, or a conducting or non-conducting amorphous, crystalline, or layered substrate. A substrate can be planar, patterned, or textured, and can further include seed layers, buffer layers, or adhesion layers such as Ti, W, or Al. Substrate temperatures can range, for example, from near room temperature (about 20° C.) to several hundred degrees Celsius, although other temperatures can be employed.

Any or all of the features and functions described herein can be combined with each other, except to the extent that such embodiments would be physically incompatible, as will be apparent to persons of ordinary skill in the art. Unless contrary to physical possibility, it is envisioned that (i) the methods or steps described herein may be performed in any sequence and/or in any combination, and (ii) the components of respective embodiments may be combined in any manner.

Unless the context clearly requires otherwise, throughout the description and the claims, the terms “comprise,” “comprising,” and the like can be understood in an inclusive sense, as opposed to an exclusive or exhaustive sense. The terms “connected,” “coupled,” or any variant thereof can mean any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words using the singular or plural number can also include the plural or singular number respectively. The word “or” in reference to a list of two or more items can cover any one of the items in the list, all of the items in the list, and any combination of the items in the list. Likewise, the term “and/or” can cover any one of the items, all of the items, and any combination of the items.

Conjunctive language such as the phrase “at least one of A, B, or C,” unless specifically stated otherwise, can be understood to convey that an item may be A alone, B alone, C alone, or any combination thereof. Such language is not generally intended to imply that all listed items must be present.

The order of steps described in connection with methods herein can be varied, and steps can be performed in any sequence, omitted, repeated, or supplemented. Ranges, values, and parameters provided herein can be understood as illustrative, and terms such as “about” or “approximately” can be understood as permitting variations that would be recognized as immaterial by persons of ordinary skill in the art.

References to equipment, materials, or suppliers can be understood as illustrative and not limiting to a particular manufacturer or configuration. Equivalent alternatives known to persons of ordinary skill in the art can be used interchangeably.

Any patents, applications, and publications cited herein can be understood as incorporated by reference in their entireties. Modifications and variations of the disclosed embodiments can be apparent to those skilled in the art in view of the teachings herein, and such modifications and variations can be considered to fall within the scope of the appended claims.

To reduce the number of claims, certain aspects of the invention may be presented below in certain claim forms, but the applicant contemplates other aspects of the invention in any number of claim forms. Any claims intended to be treated under 35 U.S.C. § 112(f) will begin with the words “means for,” but use of the term “for” in any other context is not intended to invoke treatment under § 112(f). Accordingly, the applicant reserves the right to pursue additional claims after filing this application, in either this application or in a continuing application.

What is claimed is:

1. A method of depositing an aluminum nitride thin film, comprising:
providing a substrate in a sputtering chamber;
introducing into the sputtering chamber a process gas comprising an inert gas and a nitrogen-containing gas;
maintaining a chamber pressure of the sputtering chamber below 1 Pascal;
applying to an aluminum target a sequence of negative-polarity voltage pulses, each negative-polarity pulse having a duration of 10 to 25 microseconds; and
after each negative pulse, applying to the aluminum target a positive-polarity voltage pulse having a duration of 50 to 150 microseconds, thereby depositing aluminum nitride thin film on the substrate.

2. The method of claim 1, wherein a distance between the aluminum target and the substrate is about 7 cm.

3. The method of claim 1, wherein maintaining the sputtering chamber at a pressure below 1 Pascal further comprises maintaining the chamber pressure below 0.5 Pascal.

4. The method of claim 1, wherein introducing the process gas comprises introducing the nitrogen-containing gas in an amount sufficient to deposit stoichiometric aluminum nitride while avoiding target poisoning of the aluminum target, and wherein a transition to a poisoning point is determined from a DC reactive sputtering hysteresis curve relating nitrogen pressure to target voltage in the same chamber.

5. The method of claim 1, wherein introducing the nitrogen-containing gas comprises operating the aluminum target in a transition regime between metallic and poisoned states, the transition regime being selected to achieve a deposition rate of about 60 nm/min.

6. The method of claim 1, wherein applying the sequence of negative-polarity voltage pulses comprises applying the pulses at a repetition frequency of at least 1900 Hertz at 0.5 Pascal.

7. The method of claim 1, wherein applying the positive-polarity voltage pulse comprises applying a positive voltage pulse with an amplitude between 25 volts and 50 volts.

8. The method of claim 1, wherein forming the aluminum nitride thin film comprises forming the aluminum nitride thin film with a c-axis crystallographic texture.

9. The method of claim 1, wherein the aluminum nitride thin film is formed at a deposition rate of at least about 60 nanometers per minute at a target-to-substrate distance of about 7 centimeters.

10. The method of claim 1, wherein forming the aluminum nitride thin film comprises forming the aluminum nitride thin film with a cross plane thermal conductivity of at least 120 watts per meter-kelvin at 1 μm thickness.

11. The method of claim 1, wherein applying the positive-polarity voltage pulse comprises applying the positive-polarity voltage pulse within 10 microseconds after termination of each negative-polarity pulse.

12. The method of claim 1, wherein maintaining the chamber pressure comprises maintaining the chamber pressure between 0.4 Pascal and 0.5 Pascal.

13. The method of claim 1, wherein introducing the process gas comprises introducing nitrogen as 25 to 27 percent of the total process gas flow.

14. The method of claim 1, wherein forming the 1 micrometer aluminum nitride thin film comprises forming a film having a rocking curve full width at half maximum (FWHM) of less than 4.0° at the (0002) reflection.

15. The method of claim 1, wherein forming the aluminum nitride thin film comprises forming a film having a cross plane thermal conductivity of at least 150 watts per meter-kelvin at 1 μm thickness.

16. The method of claim 1, wherein applying the sequence of negative-polarity voltage pulses comprises applying a sequence of impulse magnetron sputtering pulses having a pulse width of less than 50 microseconds at a repetition frequency of at least 1000 Hz, and wherein applying the positive-polarity voltage pulse comprises applying the positive-polarity voltage pulse to the aluminum target following each negative-polarity pulse, the positive-polarity voltage pulse having an amplitude of at least 20 volts and a duration of at least 20 microseconds.

17. The method of claim 1, wherein the aluminum nitride thin film has a surface root-mean-square roughness of less than about 0.5 nanometers when deposited at a substrate temperature of about 120° C., a target-to-substrate distance of about 7 cm, and a discharge power between about 100 watts and about 400 watts for a 2″ diameter target.

18. A sputtering system for depositing aluminum nitride, comprising:
a sputtering chamber configured to maintain a process pressure below 0.5 Pascal;
an aluminum target;
a substrate support positioned within the sputtering chamber, the substrate support being spaced from the aluminum target by approximately 7 cm;
a pulse generator configured to apply sequence of negative voltage impulse having a pulse width between 15 microseconds and 25 microseconds at a repetition frequency of at least 1900 Hz; and
a voltage source configured to apply a positive kick voltage pulse within 10 microseconds after each sputtering pulse, the positive voltage pulse having an amplitude between 30 volts and 50 volts and a duration between 50 microseconds and 150 microseconds.

19. An aluminum nitride thin film, comprising:
a c-axis crystallographic texture;
a rocking curve FWHM at the (0002) reflection of less than 4.0° when thickness is 1 micrometers; and
a cross plane thermal conductivity of at least 150 watts per meter-kelvin at thickness 1 μm.

20. The film of claim 19, wherein the aluminum nitride thin film exhibits a ballistic transport length of less than 60 nanometers, and a root-mean-square surface roughness of less than 0.5 nanometers.
